(19) United States
(12) Patent Application Publication
(10) Pub. No.: US 2020/0070279 A1
(43) Pub. Date: Mar. 5, 2020

(54) Damping method for laser activation system

(71) Applicant: VIETTEL GROUP, Ha Noi City (VN)

(72) Inventors: VAN DUC HA, Thieu Khanh Village (VN); THANH NHON NGUYEN, Thach Son Village (VN)

(73) Assignee: VIETTEL GROUP, Ha Noi City (VN)

(21) Appl. No.: 16/550,113

(22) Filed: Aug. 23, 2019

(30) Foreign Application Priority Data
Aug. 30, 2018 (VN) 1-2018-03840

(51) Int. Cl. B23K 26/02; H05K 3/00

(52) U.S. Cl. CPC B23K 26/02; H05K 3/0026

(57) ABSTRACT

The patent presents a new method of damping for laser activation systems including five steps: Step 1: Locating, clamping the batteries, PCB; Step 2: Receiving hammering force; Step 3: Damping for batteries; Step 4: Damping for PCB; Step 5: Sliding electrical contact drive. This damping method has outstanding advantages in vibration suppression in different frequency ranges and amplitudes, along with applied damping according to the requirements and characteristics of each part. As a result, the two-level damping method improves stability and longevity of the laser activation system.

### FIELD OF THE INVENTION

The patent presents a damping method for laser activation system. Specially, the damping method for the laser activation system in the gun simulator uses a two-level damping method combined with a clamping and guiding movement method.

### BACKGROUND

The laser activation system directly uses the impact force of the hammer after pulling the trigger to operate. The advantage of this system is that the compact structure and time for laser activation compared to the real gun has a lower deviation than the laser trigger system indirectly through the trigger movement. However, due to the high impact force, the small structure has a low durability leading to a short operating life of the system. Therefore, the use of a damping mechanism plays a very important role in the direct laser activation system.

Currently, the laser activation system often uses basic damping method. This method usually uses only one spring for damping while creating force to hold the batteries. The system relies on the displacement of the spring when receiving the force from the hammer to activate the elastic contact. The downside of basic damping is that there is no restriction on the relative displacement of the batteries or printed circuit board (PCB). This method, despite the use of damping springs, still has small vibrations that reduce the life of batteries and PCB inside the system. Especially for guns with intermittent firing mode or high rate of fire, it is easy to cause the phenomenon of bumping between the batteries and PCB as well as improper operation.

In order to solve the technical problems mentioned above, a novel damping method for the laser activation system is proposed. The damping method mentioned in the invention has two levels of increased damping ability in larger range of frequency and combines with clamping and movement guiding method to eliminate unwanted gaps. Therefore, the method improves system's stability and is particularly suitable for guns with high firing speed and inter-firing.

### SUMMARY

The invention presenting a new damping method for the laser activation system directly used in guns simulation includes the following steps:
Step 1: Locating, clamping the batteries, PCB;
Step 2: Receive hammering force;
Step 3: Damping for batteries;
Step 4: Damping for PCB;
Step 5: Sliding electrical contact.

The novel damping method combines fixing the position of the components and the reducing the impact of the hammering force on the components: the hammer thrust reception module uses high-stiffness springs to reduce vibration after collision; batteries and PCB fixing module using clamps and screw threads to eliminate the mounting gap; damping module for batteries with high-stiffness spring; Damping modules for spring PCB have low stiffness and high initial compression to reduce the impact on the PCB.

### DESCRIPTION OF THE DRAWINGS

FIG. 1: Description of the direct laser activation system diagram using the two-level damping method.

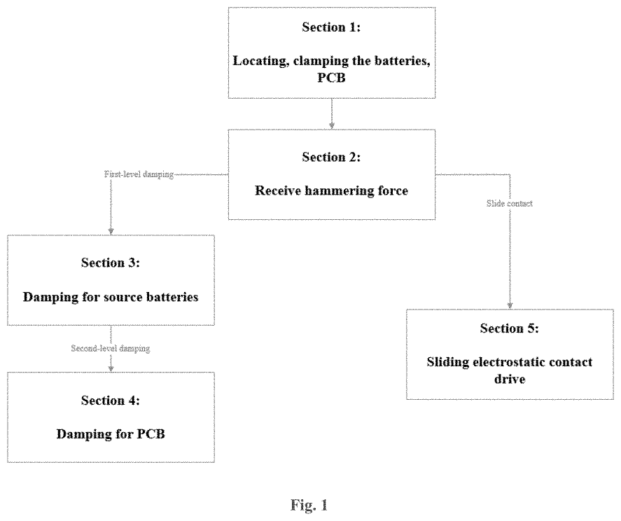

FIG. 2: Description of the relative position between components in the direct laser activation system using the two-level damping method in the normal state and the activated state.

### DETAILED DESCRIPTION OF THE INVENTION

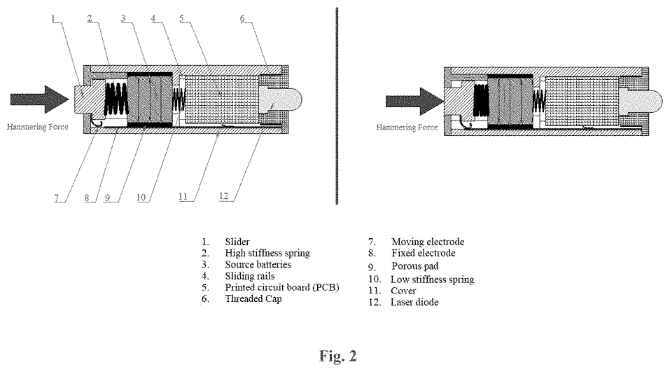

Referring to FIG. 2, in order to achieve the above purposes, the invention proposes a two-level damping method for the laser activation system that includes the following steps:

Step 1: Locating, Clamping the Batteries and PCB:

According to the invention plan, locating, clamping the source batteries and PCB using cylindrical casing to install the batteries and PCB along the direction of the hammer force thanks to the fixed batteries and PCB module with a mount and screw thread. A porous pad around the outer batteries of the batteries to eliminate the gap and ensure the batteries is installed coaxially in the cover. Inside the casing, there are two sliding rails built to locate the PCB, then use the threaded cap to match the thread on the cover to tighten the inner PCB.

Then, the batteries and the PCB are located and clamped in perpendicular to the hammering force in order to eliminate gaps that cause unwanted movement of batteries and PCB. At the same time, it reduces vibration along a certain direction.

Step 2: Receiving Hammering Force:

The reception of the hammering force is achieved by the module which is converted from the thrust force to the displacement, and is guided by a batteries and PCB fixing module.

At this step, after the batteries and PCB are fixed in a certain position, the whole laser activation system is in ready-to-operate state. When we perform a trigger operation, the hammer will move and collide with the contact point on the laser trigger system. Because the thrusting force causes a strong impact at the position of receiving hammering force, the slider has high-surface stiffness, good stress resistance and fatigue strength. Therefore, when operating in continuous collision conditions with large impact force, the slider can still ensure stable operation.

After receiving the hammering force, the slider moves along the impact force and creates a series of movement for the related parts.

Step 3: Damping for Batteries:

The damping for the source batteries is accomplished by a damping module for the batteries, which is made of a high-stiffness spring with one end attached to the slider that receives the hammering force and the other end coaxial contact with the batteries. When the slider moves due to the impact of the hammering force, the high stiffness spring is compressive and creates a damping with a large damping coefficient. Thus, the module quickly eliminates the vibration of the source batteries due to impact impulse. On the other hand, the high stiffness spring also absorbs low frequency vibrations. This is called first-level damping in the damping method of this invention.

Step 4: Damping for PCB:

The damping for PCB is accomplished by damping modules for PCB. Specifically, after first-level damping, low frequency vibrations are annihilated but high frequency vibrations still exist with small amplitudes. Because the PCB characteristics contain many small, easy-to-peel and damaged components, in this step the damping is used with a low-stiffness spring with a design that has one end in contact with the batteries and a fixed end. In the PCB, the spring is installed so that the initial compression is large to dampen the PCB. Initial compression and spring stiffness are determined based on the mass and compressive strength of the PCB. It can be seen that high frequency vibrations will impact on the position with the lowest hardness in the structure (this is the low hardness spring which absorbs all high frequency vibrations and ensures reduction of seismic forces for PCB). This provides the ability to suppress high frequency vibrations but still ensure clamping force on PCB (PCB are clamped by threaded cap and low stiffness springs). Thus the PCB is held firmly at the desired position and still eliminates all incoming vibration. This is called second-level damping in the damping method of this invention.

Step 5: Sliding Electrical Contact:

Sliding electrical contact consists of 2 separate electrode heads: moving electrode (linked to the high stiffness spring and in electrical contact with the batteries), fixed electrode (fixed at the standby and contact position power with PCB). When receiving hammering force, the high stiffness spring creates movement along the thrust force. Based on this motion, the electrode moves sliding along the spring and is in contact with the fixed electrode. Thus, power is supplied from the batteries for PCB and laser signaling. The advantage of this sliding contact is that it is capable of contacting electricity without causing impact or vibration, which helps to increase the stability of the system. This step is done immediately after the hammering force in section 2, it can be said that this step is a damping step for the electric contact, independent of the source batteries damping and PCB damping.

The invention is described in detail using the options described above. However, it is clear that for the average person in the field of invention is not limited to the plan described in the invention description. The invention may be made in a modified mode that is not outside the scope of the invention as determined by the claim points. So what is described in the patent description is for illustrative purposes only, and will not impose any restrictions on the invention.

What is claimed is:

1. The damping method for a laser activation system includes the following steps:
Step 1: Locating, clamping batteries, a PCB;
Step 2: Receiving a hammering force;
Step 3: Damping for the batteries;
Step 4: Damping for the PCB;
Step 5: Sliding an electrical contact.

2. The damping method for laser activation system according to claim 1, where:
At the step of locating, clamping the batteries, the PCB: using a cylindrical casing to install the batteries and PCB along a direction of the hammering force;
Providing a porous pad around the outer batteries of the batteries to eliminate a gap and ensure the batteries is installed coaxially in a cover; inside an enclosure, there are two sliders for locating the PCB, then use a threaded cap to match a thread on the cover to tighten the PCB in an interior of the cover;
The batteries and PCB are located and clamped in a direction perpendicular to the direction of the hammering force.

3. The damping method for laser activation system according to claim 1, where:
At the step of receiving the hammering force, carrying out a trigger, a gun hammer will rotate and collide with a contact point on the laser activation system; due to a thrusting force causing strong impact, at a position of receiving hammering force, a slider will be used with high surface stiffness and good compressive stress, fatigue strength;
After receiving the hammering force, the slider moves along the action of the impact force and creates a wire motion for the subsequent parts.

4. The damping method for laser activation system according to claim 1, where:
At the step of damping for the batteries, use a high-stiffness spring with one end linked to a slider to receive the hammering force and the other end coaxial contact with the batteries; when the slider slides in motion due to the impact of the hammering force, the high stiffness spring is compressed and creates a damping with a large damping coefficient; thereby, quickly eliminating the vibration of the source batteries due to the impact impulse.

5. The damping method for laser activation system according to claim 1, where:
At the step of damping for the PCB, using a low-stiffness spring having first and second ends with the design having the first end in contact with the source battery and the second end fixed to the PCB, the spring is installed so that an initial compression is large to dampen the PCB;
Initial compression and spring stiffness are determined based on a mass and compressive strength of the PCB; High-frequency vibrations will impact the position with a lowest stiffness, this gives the ability to suppress high-frequency vibration but still ensure clamping force on the PCB; so the PCB is held firmly at the desired position and still suppresses all incoming vibration.

6. The damping method for laser activation system according to claim 1, where:
At the step of sliding an electrical contact drive: sliding an electromagnetism contact consists of 2 separate electrode heads: a moving electrode (linked to a high stiffness spring and in electrical contact with the batteries), a fixed electrode (fixed at a standby position and in electrical contact with PCB);
When receiving hammering force, the high stiffness spring creates movement along a thrust force; Based on this motion, the moving electrode moves sliding along the spring and is in contact with the fixed electrode; thereby providing power from the batteries for PCB and laser signaling.
